(19) United States
(12) Patent Application Publication
(10) Pub. No.: US 2025/0308898 A1
(43) Pub. Date: Oct. 2, 2025

(54) DEPOSITION MASK AND METHOD OF MANUFACTURING DEPOSITION MASK

(71) Applicant: Samsung Display Co., LTD., Yongin-si (KR)

(72) Inventors: Young Jin SONG, Yongin-si (KR); Seung Hun KIM, Yongin-si (KR); Byeong Hoon CHO, Yongin-si (KR)

(21) Appl. No.: 18/928,350

(22) Filed: Oct. 28, 2024

(30) Foreign Application Priority Data
Mar. 29, 2024 (KR) 10-2024-0043052

(51) Int. Cl. H01L 21/033

(52) U.S. Cl. CPC H01L 21/0337; H01L 21/0332

(57) ABSTRACT

A deposition mask and a method of manufacturing a deposition mask includes depositing a first inorganic layer on a substrate, depositing a second inorganic layer on the first inorganic layer, forming a plurality of grooves in the second inorganic layer, and filling the plurality of grooves with an insulating layer, forming a photoresist pattern including a plurality of first openings corresponding to a cell opening on the second inorganic layer, etching the second inorganic layer at a periphery of the plurality of grooves using the photoresist pattern as a mask and exposing the cell opening by etching the substrate and the first inorganic layer from a downward direction facing a rear surface of the substrate.

This application claims priority to Korean Patent Application No. 10-2024-0043052, filed on Mar. 29, 2024, and all the benefits accruing therefrom under 35 U.S.C. § 119, the content of which in its entirety is herein incorporated by reference.

### BACKGROUND

### 1. Field

The invention relates to a deposition mask, and more particularly to a deposition mask and a method of manufacturing a deposition mask.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of about 3000 pixels or more per inch (PPI) so that a user can use it for a long time without experiencing dizziness. To this end, organic light emitting diode on silicon (OLEDoS) technology, which is a small high-resolution organic light emitting display device, is being proposed. OLEDoS is a technology for placing an organic light emitting diode (OLED) on a semiconductor wafer substrate on which a complementary metal oxide semiconductor (CMOS) is disposed.

In order to manufacture a display panel of high-resolution of about 3000 pixels or more per inch (PPI), a high-resolution deposition mask is required. As a deposition mask for manufacturing OLEDoS display panels, a mask in which an inorganic film is deposited on a silicon substrate and the deposited inorganic film is patterned to form a mask membrane is being studied. However, the mask has a high risk of breakage due to the thin thickness of the mask membrane formed of the inorganic film.

### SUMMARY

Aspects of the invention provide a deposition mask capable of reducing damage of the mask by increasing the rigidity of the mask, a method of manufacturing the deposition mask, and a method of manufacturing a display device using the deposition mask.

According to an embodiment, a method of manufacturing a deposition mask includes depositing a first inorganic layer on a substrate, depositing a second inorganic layer on the first inorganic layer, forming a plurality of grooves in the second inorganic layer, and filling the formed plurality of grooves with an insulating layer, forming a photoresist pattern including a plurality of first openings corresponding to a cell opening on the second inorganic layer including the insulating layer, etching the second inorganic layer located at a periphery of the plurality of grooves using the photoresist pattern as a mask and exposing the cell opening by etching the substrate and the first inorganic layer from a downward direction facing a rear surface of the substrate.

In an embodiment, the exposing of the cell opening includes exposing a mask membrane disposed in the cell opening.

In an embodiment, a cross-sectional structure of the mask membrane includes a second inorganic layer including the plurality of grooves and an insulating layer filling the plurality of grooves.

In an embodiment, the material of the second inorganic layer is the same as the material of the insulating layer.

In an embodiment, the material of the second inorganic layer is different from the material of the insulating layer.

In an embodiment, the substrate contains silicon (Si).

In an embodiment, the first inorganic layer contains silicon oxide (SiOₓ).

In an embodiment, the second inorganic layer contains silicon nitride (SiNₓ).

In an embodiment, the insulating layer contains silicon oxide (SiOₓ) or silicon nitride (SiNₓ).

In an embodiment, when the substrate is viewed on a plane, the width of the plurality of grooves filled with the insulating layer is uniform.

In an embodiment, when the substrate is viewed on a plane, the width of the plurality of grooves filled with the insulating layer is not uniform and is differentially formed.

In an embodiment, when the substrate is viewed on a plane, a first groove disposed adjacent to the center of the substrate has a first width, and when the substrate is viewed on a plane, a second groove disposed to be further from the center of the substrate than the first groove has a second width smaller than the first width.

In an embodiment, the method of manufacturing a deposition mask further includes forming a coating layer covering the entire surface of the substrate and the entire surface of the mask membrane using the atomic layer deposition (ALD) method.

According to an embodiment, a deposition mask includes a substrate, a first inorganic layer disposed on the substrate and a mask membrane disposed on the first inorganic layer, wherein a cross-sectional structure of the mask membrane includes a second inorganic layer including a plurality of grooves and an insulating layer filling the plurality of grooves.

In an embodiment, the material of the second inorganic layer is the same as the material of the insulating layer.

In an embodiment, the material of the second inorganic layer is different from the material of the insulating layer.

In an embodiment, the substrate contains silicon (Si).

In an embodiment, the first inorganic layer contains silicon oxide (SiOₓ), and the second inorganic layer contains silicon nitride (SiNₓ).

In an embodiment, when the substrate is viewed on a plane, the width of the plurality of grooves is filled with the insulating layer.

In an embodiment, when the substrate is viewed on a plane, a first groove disposed adjacent to the center of the substrate has a first width, and when the substrate is viewed on a plane, a second groove which is disposed further from the center of the substrate than the first groove has a second width that is smaller than the first width.

According to an embodiment, a deposition mask and a method of manufacturing a deposition mask, a deposition mask capable of reducing damage of a mask by increasing rigidity of the mask, a method of manufacturing the same, and a method of manufacturing a display device using the deposition mask is provided.

The effects of the invention are not limited to the above-described effects and other effects which are not described herein will become apparent to those skilled in the art from the following description.

### BRIEF DESCRIPTION OF THE DRAWINGS

The above and other aspects and features of the invention will become more apparent by describing in detail exemplary embodiments thereof with reference to the attached drawings, in which:

FIG. 1 is an exploded perspective view of a display device, according to an embodiment;

FIG. 2 is a schematic block diagram illustrating a display device, according to an embodiment;

FIG. 3 is an schematic equivalent circuit diagram of a first sub-pixel, according to an embodiment;

FIG. 4 is a layout diagram illustrating an example of a display panel, according to an embodiment;

FIG. 5 is a layout diagram illustrating the display area of FIG. 4, according to an embodiment;

FIG. 6 is a layout diagram illustrating the display area of FIG. 4, according to an embodiment;

FIG. 7 is a cross-sectional view illustrating a display panel taken along line I1-I1′ of FIG. 5, according to an embodiment;

FIG. 8 is a perspective view of a head mounted display, according to an embodiment;

FIG. 9 is an exploded perspective view illustrating the head mounted display of FIG. 8, according to an embodiment;

FIG. 10 is a perspective view illustrating a head mounted display, according to an embodiment;

FIG. 11 is a perspective view of a mask MK, according to an embodiment;

FIG. 12 is a schematic plan view of the mask MK, according to an embodiment;

FIG. 13 is a cross-sectional view for illustrating the processing steps of a method of manufacturing a mask, according to an embodiment;

FIG. 14 is a cross-sectional view for illustrating the processing steps of a method of manufacturing a mask, according to an embodiment;

FIG. 15 is a cross-sectional view for illustrating the processing steps of a method of manufacturing a mask, according to an embodiment;

FIG. 16 is a cross-sectional view for illustrating the processing steps of a method of manufacturing a mask, according to an embodiment;

FIG. 17 is a plan view of a mask, according to an embodiment;

FIG. 18 is a plan view of a mask, according to an embodiment; and

FIG. 19 is a cross-sectional view of a mask for illustrating the processing steps of depositing a protection film on a mask, according to an embodiment.

### DETAILED DESCRIPTION

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions may be exaggerated for clarity.

Although the terms “first”, “second”, etc. may be used herein to describe various elements, these elements should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

It will also be understood that when a layer is referred to as being “connected to” or “coupled to” another element, layer or substrate, it can be directly on the other element, layer or substrate, or intervening elements, layers or substrates may also be present. Likewise, those referred to as “Below”, “Left”, and “Right” include cases where they are directly adjacent to other elements or cases where another layer or other material is interposed. To this end, the term “connected” may refer to physical, electrical, and/or fluid connection, with or without intervening elements.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments may be described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Features of various embodiments of the invention may be combined partially or totally. As will be clearly appreciated by those skilled in the art, technically various interactions and operations are possible. Various embodiments can be practiced individually or in combination.

Hereinafter, embodiments of the invention will be described with reference to the accompanying drawings.

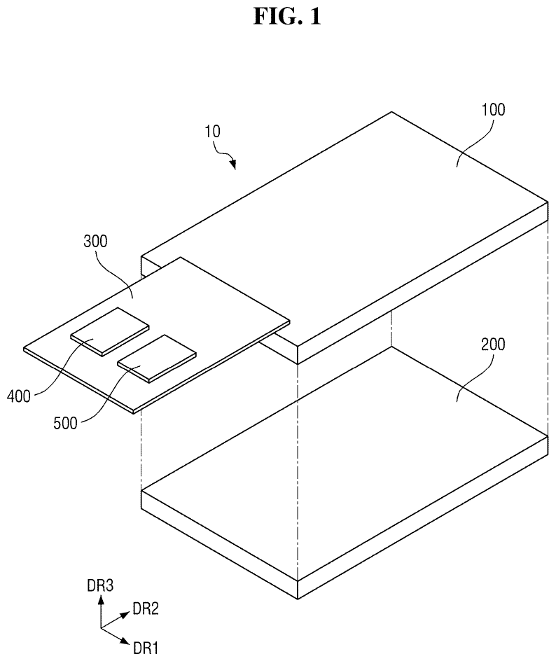

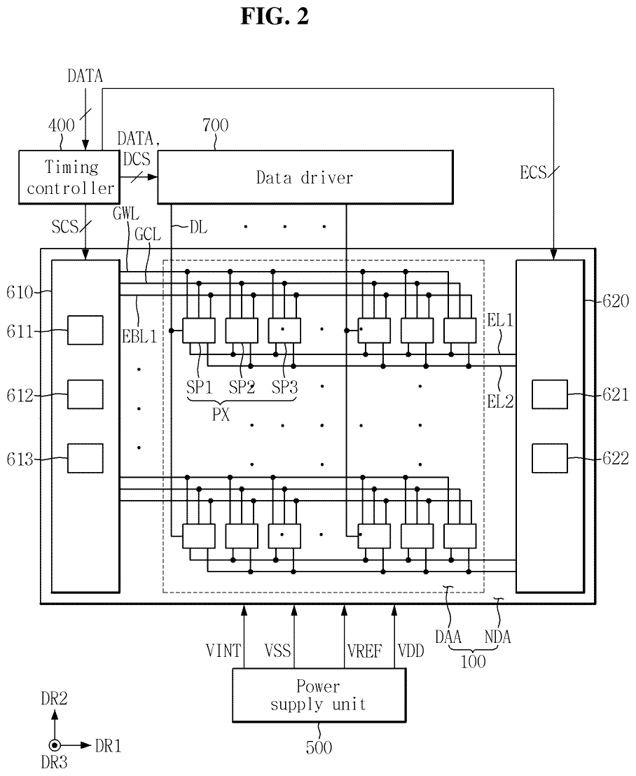

FIG. 1 is an exploded perspective view of a display device, according to an embodiment. FIG. 2 is a block diagram illustrating a display device, according to an embodiment.

In an embodiment and referring to FIGS. 1 and 2, a display device 10 is a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) terminal. In another embodiment, the display device 10 may be applied to a smart watch, a watch phone, a head mounted display (HMD) for implementing virtual reality and augmented reality, and the like.

The display device 10, according to an embodiment, includes a display panel 100, a heat dissipation layer 200, a circuit board 300, a timing control circuit 400, and a power supply circuit 500.

In an embodiment, the display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the invention is not limited thereto.

In an embodiment, the display panel 100 includes a display area DAA displaying an image and a non-display area NDA not displaying an image as shown in FIG. 2.

In an embodiment, the display area DAA includes a plurality of pixels PX, a plurality of scan lines SL, a plurality of emission control lines EL, and a plurality of data lines DL.

In an embodiment, the plurality of pixels PX may be arranged in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

In an embodiment, the plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

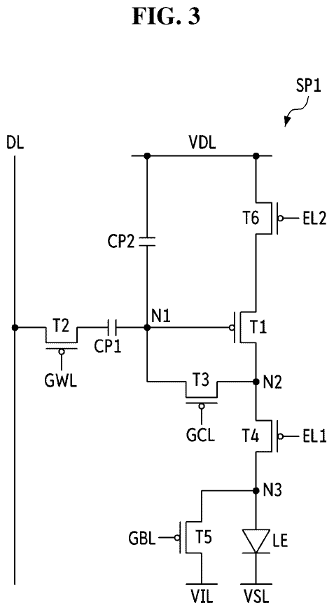

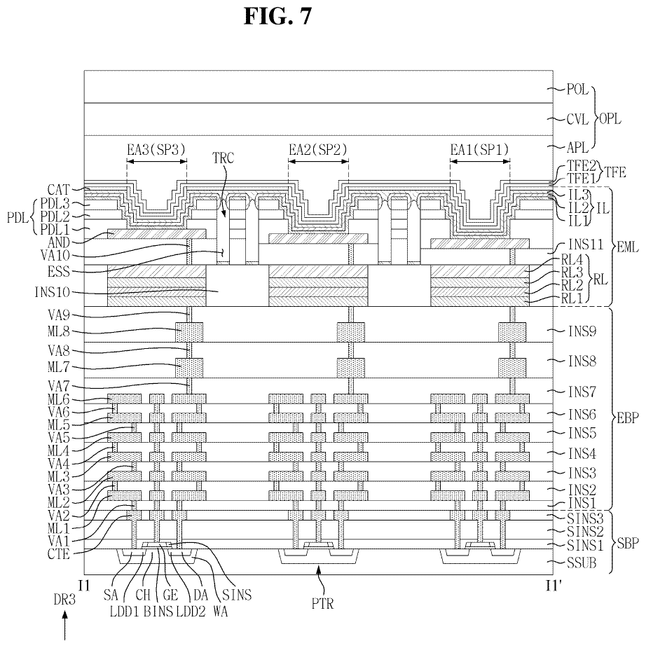

In an embodiment, the plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Moreover, each of the plurality of sub-pixels SP1, SP2, and SP3 may receive a data voltage of the data line DL in response to a write scan signal of the write scan line GWL, and emit light from the light emitting element according to the data voltage.

In an embodiment, the non-display area NDA includes a scan driver 610, an emission driver 620, and the data driver 700.

In an embodiment, the scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the invention is not limited thereto. For example, in another embodiment, the scan driver 610 and the emission driver 620 may be disposed on both the left side and the right side of the display area DAA.

In an embodiment, the scan driver 610 may include a write scan signal output unit 611, a control scan signal output unit 612, and a bias scan signal output unit 613, where each of the write scan signal output unit 611, the control scan signal output unit 612, and the bias scan signal output unit 613 may receive a scan timing control signal SCS from the timing controller circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

In an embodiment, the emission driver 620 includes a first emission control driver 621 and a second emission control driver 622, where each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

In an embodiment, the data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

In an embodiment, the heat dissipation layer 200 may overlap the display panel 100 in a third direction DR3, which is the thickness direction of the display panel 100. The heat dissipation layer 200 may be disposed on one surface of the display panel 100, for example, on the rear surface thereof and may serve to dissipate heat generated from the display panel 100. The heat dissipation layer 200 may include a metal layer such as graphite, silver (Ag), copper (Cu), or aluminum (Al) having high thermal conductivity.

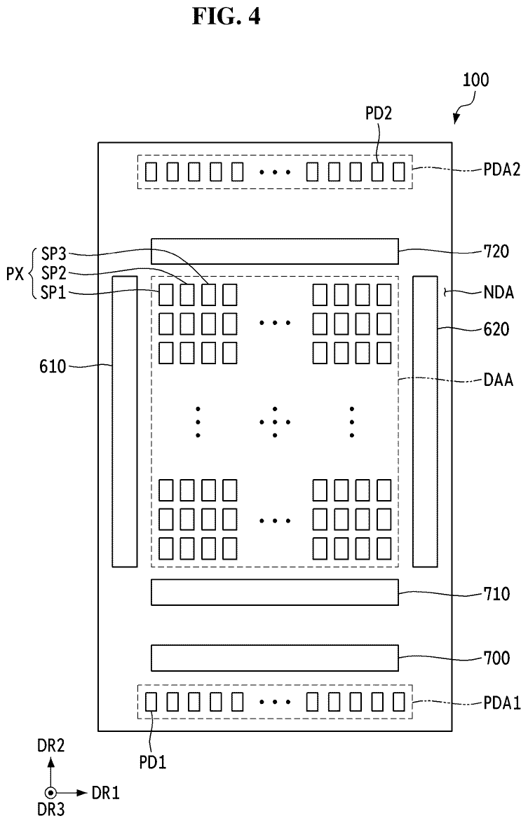

In an embodiment, the circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this embodiment, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

In an embodiment, the timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

In an embodiment, the power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

In an embodiment, each of the timing control circuit 400 and the power supply circuit 500 may be formed as an integrated circuit (IC) and attached to one surface of the circuit board 300. In this embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In this embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first sub-pixel, according to an embodiment.

In an embodiment and referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this embodiment, the first driving voltage VSS may be lower than the third driving voltage VINT. The second driving voltage VDD may be higher than the third driving voltage VINT.

In an embodiment, the first sub-pixel SP1 includes a plurality of transistors T1 to T6, a light emitting element LE, a first capacitor CP1, and a second capacitor CP2.

In an embodiment, the light emitting element LE emits light in response to a driving current Ids this is flowing through the channel of the first transistor T1, where the emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the invention is not limited thereto. For example, in another embodiment, the light emitting element LE may be an inorganic light emitting element including a first electrode, a second electrode, and an inorganic semiconductor disposed between the first electrode and the second electrode, in which case the light emitting element LE may be a micro light emitting diode.

In an embodiment, the first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of the sixth transistor T6, and a drain electrode connected to a second node N2.

In an embodiment, the second transistor T2 may be disposed between one electrode of the first capacitor CP1 and the data line DL, where the second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

In an embodiment, the third transistor T3 may be disposed between the first node N1 and the second node N2, where the third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

In an embodiment, the fourth transistor T4 may be connected between the second node N2 and a third node N3, where the fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

In an embodiment, the fifth transistor T5 may be disposed between the third node N3 and the third driving voltage line VIL, where the fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

In an embodiment, the sixth transistor T6 may be disposed between the source electrode of the first transistor T1 and the second driving voltage line VDL, where the sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

In an embodiment, the first capacitor CP1 is formed between the first node N1 and the drain electrode of the second transistor T2 and includes one electrode connected to the drain electrode of the second transistor T2 and the other electrode connected to the first node N1.

In an embodiment, the second capacitor CP2 is formed between the gate electrode of the first transistor T1 and the second driving voltage line VDL and includes one electrode connected to the gate electrode of the first transistor T1 and the other electrode connected to the second driving voltage line VDL.

In an embodiment, the first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

In an embodiment, each of the transistors T1 to T6 may be a metal-oxide-semiconductor field effect transistor (MOSFET). For example, each of the transistors T1 to T6 may be a P-type MOSFET, however the invention is not limited thereto. In another embodiment, each of the transistors T1 to T6 may be an N-type MOSFET. In still another embodiment, some of the transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, in another embodiment, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is omitted in the present specification.

FIG. 4 is a layout diagram illustrating an example of a display panel, according to an embodiment.

In an embodiment and referring to FIG. 4, the display area DAA of the display panel 100 includes the plurality of pixels PX arranged in a matrix form. The non-display area NDA of the display panel 100 includes the scan driver 610, the emission driver 620, the data driver 700, a first distribution circuit 710, a second distribution circuit 720, the first pad portion PDA1, and a second pad portion PDA2.

In an embodiment, the scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the invention is not limited thereto, and, in another embodiment, the scan driver 610 and the emission driver 620 may be disposed on both the first side and the second side of the display area DAA.

In an embodiment, the first pad portion PDA1 may include the plurality of first pads PD1 connected to pads or bumps of the circuit board 300 through a conductive adhesive member. The first pad portion PDA1 may be disposed on the third side of the non-display area NDA. For example, the first pad portion PDA1 may be disposed on one side of the non-display area NDA in the second direction DR2.

In an embodiment, the first pad portion PDA1 may be disposed outside the data driver 700 in the second direction DR2. That is, the first pad portion PDA1 may be disposed closer to the edge of the display panel 100 than the data driver 700.

In an embodiment, the second pad portion PDA2 may include a plurality of second pads PD2 corresponding to inspection pads that test whether the display panel 100 operates normally. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

In an embodiment, the first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL (See FIG. 3), and as a result, the number of the plurality of first pads PD1 may be reduced. The first distribution circuit 710 may be disposed on the third side of the non-display area NDA of the display panel 100. For example, the first distribution circuit 710 may be disposed on one side of the non-display area NDA in the second direction DR2. That is, the first distribution circuit 710 may be disposed on the lower side of the non-display area NDA.

In an embodiment, the second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the non-display area NDA of the display panel 100. For example, the second distribution circuit 720 may be disposed on the other side of the non-display area NDA in the second direction DR2. That is, the second distribution circuit 720 may be disposed on the upper side of the non-display area NDA.

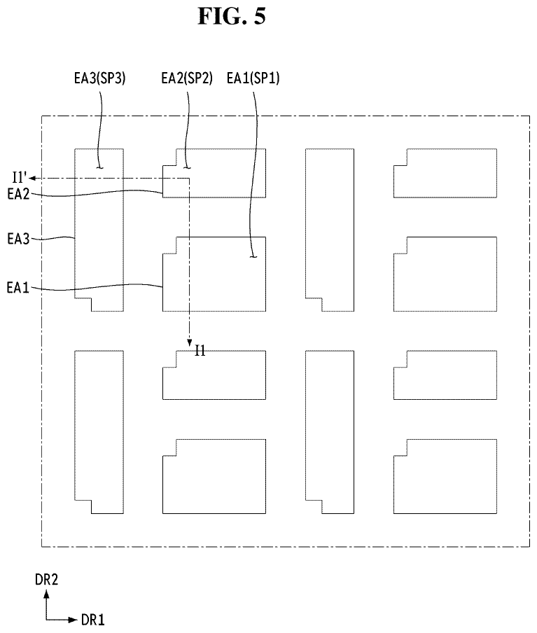

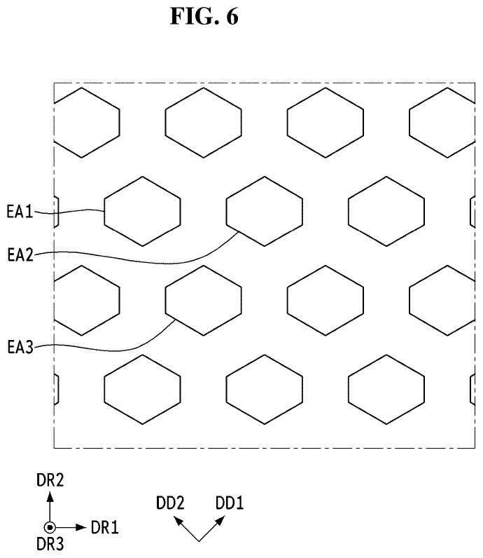

FIGS. 5 and 6 are layout diagrams illustrating embodiments of the display area of FIG. 4, according to an embodiment.

In an embodiment and referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

In an embodiment, the maximum length of the third emission area EA3 in the first direction DR1 may be smaller than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

In an embodiment, the maximum length of the third emission area EA3 in the second direction DR2 may be longer than the maximum length of the first emission area EA1 in the second direction DR2 and the maximum length of the second emission area EA2 in the second direction DR2. The maximum length of the first emission area EA1 in the second direction DR2 may be longer than the maximum length of the second emission area EA2 in the second direction DR2.

In an embodiment, the first emission area EA1, the second emission area EA2, and the third emission area EA3 may have, in a plan view, a hexagonal shape formed of six straight lines as shown in FIGS. 5 and 6, but the invention is not limited thereto. The first emission area EA1, the second emission area EA2, and the third emission area EA3 may have a polygonal shape other than a hexagon, a circular shape, an elliptical shape, or an atypical shape in a plan view.

In an embodiment and as shown in FIG. 5, in each of the plurality of pixels PX, the first emission area EA1 and the second emission area EA2 may be disposed adjacent to each other in the first direction DR1. Further, the first emission area EA1 and the third emission area EA3 may be disposed adjacent to each other in the first direction DR1. In addition, the second emission area EA2 and the third emission area EA3 may be disposed adjacent to each other in the second direction DR2. The area of the first emission area EA1, the area of the second emission area EA2, and the area of the third emission area EA3 may be different.

In another embodiment, as shown in FIG. 6, the first emission area EA1 and the second emission area EA2 may be disposed adjacent to each other in the first direction DR1, but the second emission area EA2 and the third emission area EA3 may be disposed adjacent to each other in a first diagonal direction DD1, and the first emission area EA1 and the third emission area EA3 may be disposed adjacent to each other in a second diagonal direction DD2. The first diagonal direction DD1 may be a direction between the first direction DR1 and the second direction DR2 and may refer to a direction that is inclined by 45 degrees with respect to the first direction DR1 and the second direction DR2, and the second diagonal direction DD2 may be a direction that is directed perpendicular to the first diagonal direction DD1.

In an embodiment, the first emission area EA1 may emit light of a first color, the second emission area EA2 may emit light of a second color, and the third emission area EA3 may emit light of a third color. The light of the first color may be light of a blue wavelength band, the light of the second color may be light of a green wavelength band, and the light of the third color may be light of a red wavelength band. For example, in an embodiment, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIGS. 5 and 6 that each of the plurality of pixels PX includes three emission areas EA1, EA2, and EA3, but the invention is not limited thereto. That is, each of the plurality of pixels PX may include four emission areas.

In addition, the layout of the emission areas of the plurality of pixels PX is not limited to that illustrated in FIGS. 5 and 6. For example, in another embodiment, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side as shown in FIG. 6.

FIG. 7 is a cross-sectional view illustrating an example of a display panel taken along line I1-I1′ of FIG. 5, according to an embodiment.

In an embodiment and referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

In an embodiment, the semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the transistors T1 to T6 described with reference to FIG. 4.

In an embodiment, the semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, in an embodiment, when the first type impurity is a p-type impurity, the second type impurity may be an n-type impurity. In another embodiment, when the first type impurity is an n-type impurity, the second type impurity may be a p-type impurity.

In an embodiment, each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

In an embodiment, each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

In an embodiment, each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

In an embodiment, a first semiconductor insulating layer SINS1 may be disposed on the semiconductor substrate SSUB and may be formed of silicon carbonitride (SiCN) or a silicon oxide (SiOₓ)-based inorganic layer, but the invention is not limited thereto.

In an embodiment, a second semiconductor insulating layer SINS2 may be disposed on the first semiconductor insulating layer SINS1 and may be formed of a silicon oxide (SiOₓ)-based inorganic layer, but the invention is not limited thereto.

In an embodiment, the plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, a third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOₓ)-based inorganic layer, but the invention is not limited thereto.

In an embodiment, the semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

In an embodiment, the light emitting element backplane EBP includes a plurality of conductive layers ML1 to ML8, a plurality of vias VA1 to VA9. In addition, the light emitting element backplane EBP includes a plurality of insulating layers INS1 to INS9 disposed between the first to eighth conductive layers ML1 to ML8.

In an embodiment, the conductive layers ML1 to ML8 serve to connect the plurality of contact terminals CTE exposed from the semiconductor backplane SBP to thereby implement the circuit of the first sub-pixel SP1 shown in FIG. 3. For example, the transistors T1 to T6 are merely formed on the semiconductor backplane SBP, and the connection of the transistors T1 to T6 and the capacitors C1 and C2 is accomplished through the conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the conductive layers ML1 to ML8.The first insulating layer INS1 may be disposed on the semiconductor backplane SBP. Each of the first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

In an embodiment, the second insulating layer INS2 may be disposed on the first insulating layer INS1 and the first conductive layers ML1. Each of the second vias VA2 may penetrate the second insulating layer INS2 and be connected to the exposed first conductive layer ML1. Each of the second conductive layers ML2 may be disposed on the second insulating layer INS2 and may be connected to the second via VA2.

In an embodiment, the third insulating layer INS3 may be disposed on the second insulating layer INS2 and the second conductive layers ML2. Each of the third vias VA3 may penetrate the third insulating layer INS3 and be connected to the exposed second conductive layer ML2. Each of the third conductive layers ML3 may be disposed on the third insulating layer INS3 and may be connected to the third via VA3.

In an embodiment, a fourth insulating layer INS4 may be disposed on the third insulating layer INS3 and the third conductive layers ML3. Each of the fourth vias VA4 may penetrate the fourth insulating layer INS4 and be connected to the exposed third conductive layer ML3. Each of the fourth conductive layers ML4 may be disposed on the fourth insulating layer INS4 and may be connected to the fourth via VA4.

In an embodiment, a fifth insulating layer INS5 may be disposed on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be disposed on the fifth insulating layer INS5 and may be connected to the fifth via VA5.

In an embodiment, a sixth insulating layer INS6 may be disposed on the fifth insulating layer INS5 and the fifth conductive layers ML5. Each of the sixth vias VA6 may penetrate the sixth insulating layer INS6 and be connected to the exposed fifth conductive layer ML5. Each of the sixth conductive layers ML6 may be disposed on the sixth insulating layer INS6 and may be connected to the sixth via VA6.

In an embodiment, a seventh insulating layer INS7 may be disposed on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be disposed on the seventh insulating layer INS7 and may be connected to the seventh via VA7.

In an embodiment, an eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

In an embodiment, the conductive layers ML1 to ML8 and the vias VA1 to VA8 may be formed of substantially the same material. The conductive layers ML1 to ML8 and the vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The vias VA1 to VA8 may be made of substantially the same material and insulating layers INS1 to INS8 may be formed of a silicon oxide (SiOₓ)-based inorganic layer, but the invention is not limited thereto.

In an embodiment, the thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, in an embodiment, the thickness of the first conductive layer ML1 may be approximately 1360 Å, the thickness of each of the second conductive layer ML2, the third conductive layer ML3, the fourth conductive layer ML4, the fifth conductive layer ML5, and the sixth conductive layer ML6 may be approximately 1440 Å and the thickness of each of the first via VA1, the second via VA2, the third via VA3, the fourth via VA4, the fifth via VA5, and the sixth via VA6 may be approximately 1150 Å.

In an embodiment, the thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, in an embodiment, the thickness of each of the seventh conductive layer ML7 and the eighth conductive layer ML8 may be approximately 9000 Å and the thickness of each of the seventh via VA7 and the eighth via VA8 may be approximately 6000 Å.

In an embodiment, the ninth insulating layer INS9 may be disposed on the eighth insulating layer INS8 and the eighth conductive layer ML8. The ninth insulating layer INS9 may be formed of a silicon oxide (SiOₓ)-based inorganic layer, but the invention is not limited thereto.

In an embodiment, each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

In an embodiment, the display element layer EML may be disposed on the light emitting element backplane EBP and may include light emitting elements LE each including a reflective electrode layer RL, tenth and eleventh insulating layers INS10 and INS11, a tenth via VA10, the first electrode AND, a light emitting stack IL, and a second electrode CAT and a pixel defining layer PDL.

In an embodiment, the reflective electrode layer RL may be disposed on the ninth insulating layer INS9 and may include at least one reflective electrode RL1, RL2, RL3, and RL4. For example, the reflective electrode layer RL may include first to fourth reflective electrodes RL1, RL2, RL3, and RL4, respectively, as shown in FIG. 7.

In an embodiment, each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

In an embodiment, tach of second reflective electrodes RL2 may be disposed on the first reflective electrode RL1 and may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

In an embodiment, each of the third reflective electrodes RL3 may be disposed on the second reflective electrode RL2 and may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

In an embodiment, the fourth reflective electrodes RL4 may be respectively disposed on the third reflective electrodes RL3 and may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

In an embodiment, since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, in an embodiment, the thickness of each of the first reflective electrode RL1, the third reflective electrode RL3, and the fourth reflective electrode RL4 may be approximately 100 Å, and the thickness of the second reflective electrode RL2 may be 850 Å.

In an embodiment, the tenth insulating layer INS10 may be disposed on the ninth insulating layer INS9, where the tenth insulating layer INS10 may be disposed between the reflective electrode layers RL to be adjacent to each other in a horizontal direction. The tenth insulating layer INS10 may be formed of a silicon oxide (SiOₓ)-based inorganic layer, but the invention is not limited thereto.

In an embodiment, the eleventh insulating layer INS11 may be disposed on the tenth insulating layer INS10 and the reflective electrode layer RL and may be formed of a silicon oxide (SiOₓ)-based inorganic layer, but the invention is not limited thereto. The tenth insulating layer INS10 and the eleventh insulating layer INS11 may be an optical auxiliary layer through which light reflected by the reflective electrode layer RL passes, among light emitted from the light emitting elements LE.

In an embodiment and in order to match the resonance distance of the light emitted from the light emitting elements LE in at least one of the first sub-pixel SP1, the second sub-pixel SP2, or the third sub-pixel SP3, the tenth insulating layer INS10 or the eleventh insulating layer INS11 may not be disposed under the first electrode AND. For example, the first electrode AND of the first sub-pixel SP1 may be directly disposed on the reflective electrode layer RL. The eleventh insulating layer INS11 may be disposed under the first electrode AND of the second sub-pixel SP2. The tenth insulating layer INS10 and the eleventh insulating layer INS11 may be disposed under the first electrode AND of the third sub-pixel SP3.

In summary, in an embodiment, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating layer INS10 and the eleventh insulating layer INS11 may be set in each of the first sub-pixel SP1, the second sub-pixel SP2, and the third sub-pixel SP3. For example, the distance between the first electrode AND and the reflective electrode layer RL in the third sub-pixel SP3 may be larger than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be larger than the distance between the first electrode AND and the reflective electrode layer RL in the first sub-pixel SP1. However, the invention is not limited thereto.

In addition, although the tenth insulating layer INS10 and the eleventh insulating layer INS11 are illustrated in the embodiment of the present specification, a twelfth insulating layer disposed under the first electrode AND of the first sub-pixel SP1 may be added. In this embodiment, the eleventh insulating layer INS11 and the twelfth insulating layer may be disposed under the first electrode AND of the second sub-pixel SP2, and the tenth insulating layer INS10, the eleventh insulating layer INS11, and the twelfth insulating layer may be disposed under the first electrode AND of the third sub-pixel SP3.

In an embodiment, each of the tenth vias VA10 may penetrate the tenth insulating layer INS10 and/or the eleventh insulating layer INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be smaller than the thickness of the tenth via VA10 in the third sub-pixel SP3.

In an embodiment, the first electrode AND of each of the light emitting elements LE may be disposed on the tenth insulating layer INS10 and connected to the tenth via VA10. The first electrode AND of each of the light emitting elements LE may be connected to the drain region DA or source region SA of the pixel transistor PTR through the tenth via VA10, the reflective electrodes RL1 to RL4, the vias VA1 to VA9, the conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

In an embodiment, the pixel defining layer PDL may be disposed on a part of the first electrode AND of on each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

In an embodiment, the first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

In an embodiment, the pixel defining layer PDL may include first to third pixel defining layers PDL1, PDL2, and PDL3, respectively. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but the invention is not limited thereto. The first pixel defining layer PDL1, the second pixel defining layer PDL2, and the third pixel defining layer PDL3 may each have a thickness of about 500 Å.

In an embodiment, when the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

In an embodiment, the light emitting stack IL may include a plurality of intermediate layers, where the light emitting stack IL may include a first stack layer IL1, a second stack layer IL2, and a third stack layer IL3 emitting different lights. The first stack layer IL1, the second stack layer IL2, and the third stack layer IL3 are not connected consecutively and are disconnected between the adjacent sub-pixels.

In an embodiment, the first stack layer IL1 may have a structure in which a first hole transport layer, a first organic light emitting layer that emits light of the first color, and a first electron transport layer are sequentially stacked. The first stack layer IL1 may be disposed on the first electrodes AND and the pixel defining layer PDL in the first emission area EA1 of the first sub-pixel SP1.

In an embodiment, the second stack layer IL2 may have a structure in which a second hole transport layer, a second organic light emitting layer that emits light of the third color, and a second electron transport layer are sequentially stacked. The second stack layer IL2 may be disposed on the first electrodes AND and the pixel defining layer PDL in the second emission area EA2 of the second sub-pixel SP2.

In an embodiment, the third stack layer IL3 may have a structure in which a third hole transport layer, a third organic light emitting layer that emits light of the second color, and a third electron transport layer are sequentially stacked. The third stack layer IL3 may be disposed on the first electrodes AND and the pixel defining layer PDL in the first emission area EA1 of the third sub-pixel SP3.

In an embodiment, the second electrode CAT may be disposed on the third stack layer IL3 and the pixel defining layer PDL and may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

In an embodiment, the encapsulation layer TFE may be disposed on the display element layer EML and may include at least one inorganic layer TFE1 and TFE2 to prevent oxygen or moisture from permeating into the display element layer EML. For example, the encapsulation layer TFE may include the first encapsulation inorganic layer TFE1, and a second encapsulation inorganic layer TFE2.

In an embodiment, the first encapsulation inorganic layer TFE1 may be disposed on the second electrode CAT and may be formed as a multilayer in which one or more inorganic layers selected from silicon nitride (SiNₓ), silicon oxy nitride (SiON), and silicon oxide (SiOₓ) are alternately stacked. The first encapsulation inorganic layer TFE1 may be formed by a chemical vapor deposition (CVD) process.

In an embodiment, the second encapsulation inorganic layer TFE2 may be disposed on the first encapsulation inorganic layer TFE1 and may be formed of titanium oxide (TiOₓ) or aluminum oxide layer (AlOₓ) but the invention is not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

In an embodiment, an organic layer APL may be a layer for increasing the interfacial adhesion between the encapsulation layer TFE and the cover layer CVL and may be an organic layer such as acrylic resin, epoxy resin, phenolic resin, polyamide resin, or polyimide resin.

In an embodiment, the cover layer CVL may be disposed on the organic layer APL and may be a glass substrate or a polymer resin.

In an embodiment, the polarizing plate POL may be disposed on one surface of the cover layer CVL, where the polarizing plate POL may be a structure for preventing visibility degradation caused by reflection of external light. The polarizing plate POL may include a linear polarizing plate and a phase retardation film. For example, the phase retardation film may be a λ/4 plate (quarter-wave plate), but an exemplary embodiment of the present disclosure is not limited thereto.

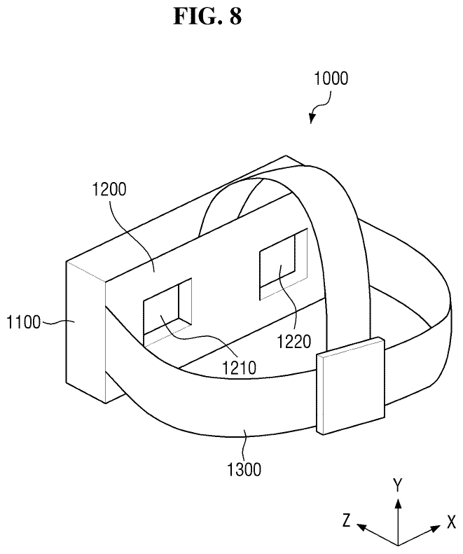

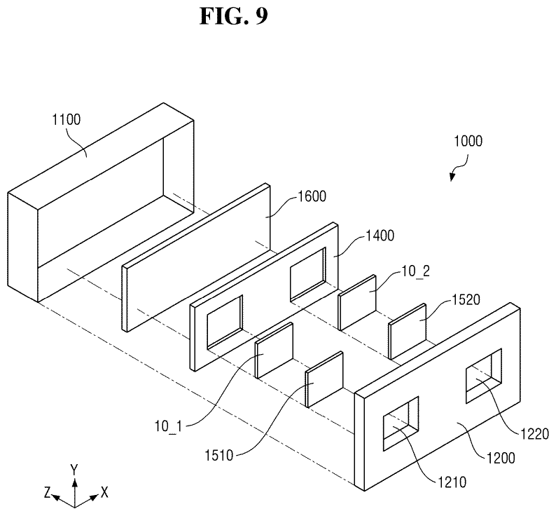

FIG. 8 is a perspective view illustrating a head mounted display, according to an embodiment. FIG. 9 is an exploded perspective view illustrating an example of the head mounted display of FIG. 8, according to an embodiment.

In an embodiment and referring to FIGS. 8 and 9, a head mounted display 1000 includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

In an embodiment, the first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, a description of the first display device 10_1 and the second display device 10_2 will be omitted.

In an embodiment, the first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

In an embodiment, the middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

In an embodiment, the control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into digital video data DATA and transmit the digital video data DATA to the first display device 10_1 and the second display device 10_2 through the connector.

In an embodiment, the control circuit board 1600 may transmit the digital video data DATA corresponding to a left-eye image optimized for the user's left eye to the first display device 10_1 and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

In an embodiment, the display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 8 and 9 illustrate that the first eyepiece 1210 and the second eyepiece 1220 are disposed separately, but the invention is not limited thereto. The first eyepiece 1210 and the second eyepiece 1220 may be combined into one.

In an embodiment, the first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

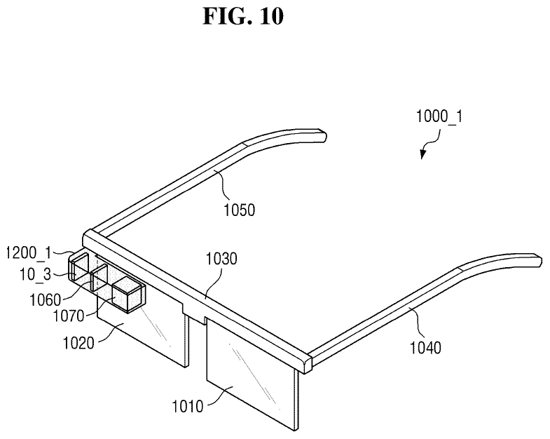

In an embodiment, the head mounted band 1300 serves to secure the display device housing 1100 to the user's head such that the first eyepiece 1210 and the second eyepiece 1220 of the housing cover 1200 remain disposed to be aligned with the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display, according to an embodiment.

In an embodiment and referring to FIG. 10, a head mounted display 1000_1 may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

In an embodiment, the display device housing 1200_1 may include the display device 10_3, the optical member 1060, and the optical path changing member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the invention is not limited thereto. For example, in another embodiment, the display device housing 1200_1 may be disposed at the left end of the support frame 1030, and in this case, the image of the display device 10_3 may be provided to the user's left eye. In another embodiment, the display device housing 1200_1 may be disposed at both the left and right ends of the support frame 1030, and in this case, the user may view the image displayed on the display device 10_3 through both the left and right eyes.

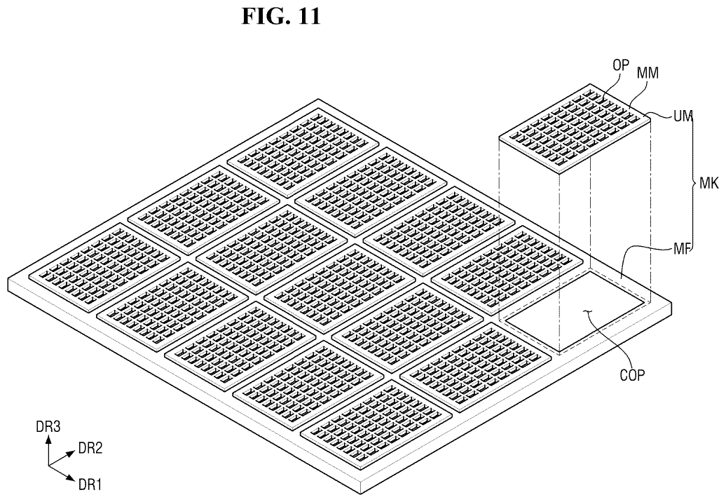

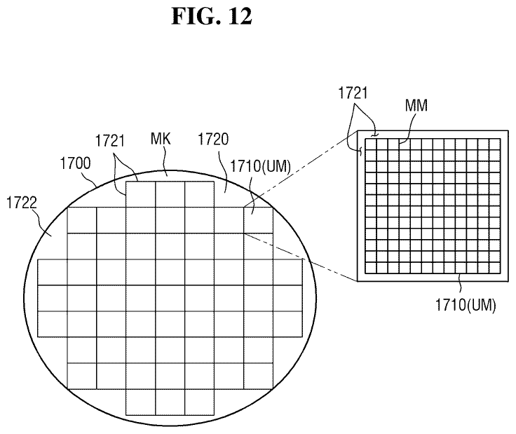

FIG. 11 is a perspective view of a mask MK, according to an embodiment. FIG. 12 is a schematic plan view of the mask MK, according to an embodiment. FIG. 11 is a perspective view illustrating a state in which one unit mask UM is separated from a plurality of unit masks. The mask MK, according to the embodiment illustrated in FIGS. 11 and 12, may be used in a process of depositing at least a portion of the light emitting stack IL described with reference to FIG. 7. For example, the light emitting stack IL may be configured to emit light of different colors in the sub-pixels SP1 through SP3.

In an embodiment and referring to FIGS. 11 and 12, the mask MK may be a shadow mask in which mask membranes MM are disposed on a silicon substrate 1700. The mask MK, according to an embodiment, may be referred to as a “silicon mask.”

According to an embodiment, the mask MK may include the silicon substrate 1700, and the mask membranes MM may be disposed on the silicon substrate 1700. The mask membranes MM may be respectively disposed in cell areas 1710 to be arranged in a matrix form, and each cell area 1710 may be surrounded by a mask rib area 1721. A portion of the silicon substrate 1700 may be disposed in the mask rib area 1721. The mask rib area 1721 may support the mask membranes MM.

A mask membrane MM may be a part of a unit mask UM disposed in each of the cell areas 1710.

In an embodiment, the silicon substrate 1700 may include a plurality of cell areas 1710 and a mask frame area 1720 excluding the cell areas 1710. The mask frame area 1720 may include the mask rib area 1721 surrounding each cell area 1710 and an outer frame area 1722 disposed at an outermost periphery of the silicon substrate 1700. A mask frame MF may be disposed in the mask frame area 1720, where the mask frame MF may include mask ribs surrounding the cell areas 1710.

The mask rib area 1721 may be an area that separates the cell areas 1710. For example, the cell areas 1710 may be arranged in a matrix form and the mask ribs disposed in the mask rib area 1721 may surround the outside of the mask membrane MM disposed in each of the cell areas 1710.

In an embodiment, a cell opening COP and a unit mask UM that masks at least a portion of the cell opening COP may be disposed in each of the cell areas 1710 of the mask substrate 1700.

A plurality of cell openings COP may penetrate the mask frame MF along the thickness direction (e.g., the third direction DR3) of the mask MK, where the cell openings COP may be formed by partially etching the silicon substrate 1700 from a back side.

In an embodiment, each unit mask UM may include a mask membrane MM, and the mask membrane MM may include mask openings.

The mask openings of each mask membrane MM may be referred to as “holes” or “mask holes”. The mask openings may penetrate the unit masks UM along the thickness direction (e.g., the third direction DR3) of the mask MK.

One unit mask UM can be used in a deposition process of one display panel 100. In the present disclosure, the term “unit mask UM” can be replaced with a term such as “mask unit UM” or “unit mask UM”.

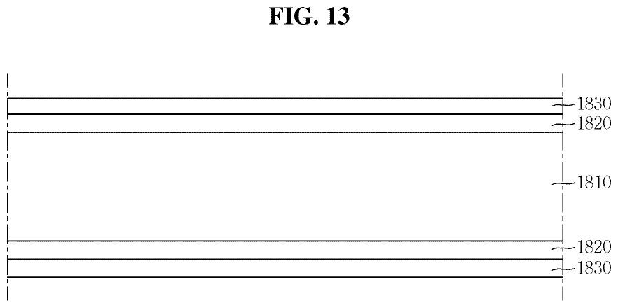

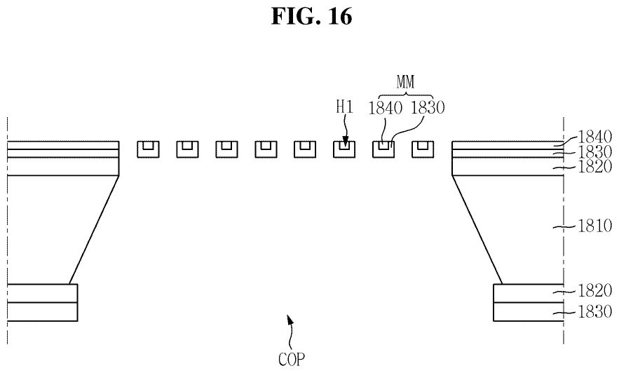

FIGS. 13 to 16 are cross-sectional views illustrating processing steps of a method of manufacturing a mask according to an embodiment. For example, FIG. 16 may be a cross-sectional view in which a portion of a mask is cut, and FIGS. 13 to 16 may be drawings illustrating a process of manufacturing a mask illustrated in FIG. 16 in sequential order.

Hereinafter, a method of manufacturing a mask, according to an embodiment, will be described with reference to FIGS. 13 to 16.

In an embodiment and referring to FIG. 13, a substrate 1810 may be prepared, where The substrate 1810 may include silicon (Si). The substrate 1810 may be referred to as a membrane substrate 1810 or a body substrate 1810, but the present disclosure is not limited thereto.

When the substrate 1810 is prepared, inorganic layers 1820 and 1830 may be deposited on the substrate 1810. The inorganic layers 1820 and 1830 may be deposited on the entire surface of the substrate 1810. For example, the inorganic layers 1820 and 1830 may be deposited on the front surface, the side surface and the rear surface.

According to an embodiment, the inorganic layer 1820 may include a single layer. For example, the inorganic layer 1820 may include a first inorganic layer 1820, and the first inorganic layer 1820 may include at least any one of silicon (Si), silicon nitride (SiNₓ), silicon oxynitride (SiOₙ), silicon oxide (SiOₓ), titanium oxide (TiOₓ), amorphous silicon (a-Si), and aluminum oxide layer (AlOₓ).

According to another embodiment, the inorganic layers 1820 and 1830 may include multiple layers. For example, the inorganic layer may include a first inorganic layer 1820 and a second inorganic layer 1830 disposed on the first inorganic layer 1820. The first inorganic layer 1820 may include a silicon oxide (SiOₓ) and the second inorganic layer 1830 may include a silicon nitride (SiNₓ). However, the material of each of the first inorganic layer 1820 and the second inorganic layer 1830 is not limited thereto. For example, in an embodiment, the material of each of the first inorganic layer 1820 and the second inorganic layer 1830 may include at least any one of silicon (Si), silicon nitride (SiNₓ), silicon oxynitride (SiOₙ), silicon oxide (SiOₓ), titanium oxide (TiOₓ), amorphous silicon (a-Si), and aluminum oxide layer (A1Oₓ).

Hereinafter, an embodiment of depositing the first inorganic layer 1820 and the second inorganic layer 1830 on the substrate 1810 will be described.

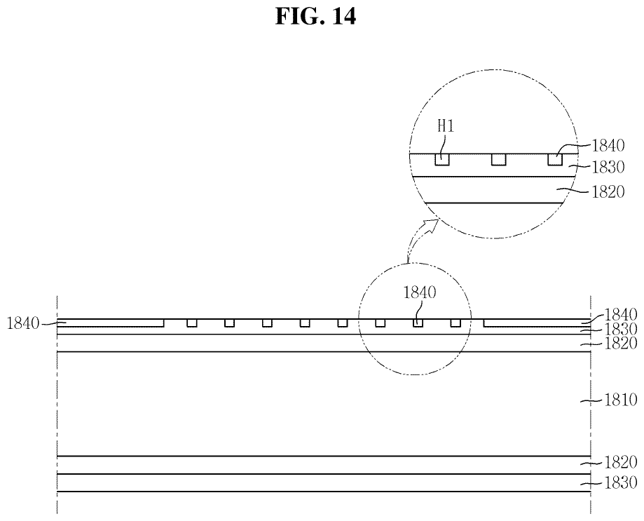

In an embodiment and referring to FIG. 14, a plurality of grooves Hl may be formed in the second inorganic layer 1830, and an insulating layer 1840 filling the plurality of grooves H1 may be deposited. For example, the insulating layer 1840 may include at least any one of silicon (Si), silicon nitride (SiNₓ), silicon oxynitride (SiOₙ), silicon oxide (SiOₓ), titanium oxide (TiOₓ), amorphous silicon (a-Si), and aluminum oxide layer (AlOₓ).

In an embodiment, a process of forming the groove H1 in the second inorganic layer 1830 may include the steps as described below. First, a photoresist pattern (not illustrated) having a plurality of openings (not illustrated) is formed in the second inorganic layer 1830 corresponding to a plurality of cell areas 1710 (see FIG. 12) (or a cell opening COP). Subsequently, the second inorganic layer 1830 corresponding to the plurality of cell areas 1710 is etched in a predetermined thickness by using the photoresist pattern as a mask to form a plurality of grooves H1 of the second inorganic layer 1830. Accordingly, the second inorganic layer 1830 has the plurality of grooves H1 in the plurality of cell areas 1710. In another embodiment, the plurality of cell areas 1710 may have a surface having irregular shapes in the plurality of cell areas 1710.

In an embodiment, after forming the grooves H1 in the second inorganic layer 1830, a process of filling the insulating layer 1840 in the groove Hl may be performed. First, the insulating layer 1840 is deposited onto the substrate 1810 including the second inorganic layer 1830. The insulating layer 1840 may include at least any one of silicon (Si), silicon nitride (SiNₓ), silicon oxynitride (SiOn), silicon oxide (SiOₓ), titanium oxide (TiOₓ), amorphous silicon (a-Si), and aluminum oxide layer (AlOₓ). Subsequently, a photoresist pattern (not illustrated) may be formed on the insulating layer 1840, and the insulating layer 1840 deposited on the upper surface of the second inorganic layer 1830 except the groove H1 may be etched by using the photoresist pattern as a mask.

According to an embodiment, the patterning process of the insulating layer 1840 may not use a photoetching process using the photoresist pattern. For example, after depositing the insulating layer 1840 onto the substrate 1810 including the second inorganic layer 1830, a chemical mechanical polishing (CMP) process polishing the upper surface of the substrate 1810 may be performed. Accordingly, the insulating layer 1840 deposited onto the upper surface of the second inorganic layer 1830 except the groove Hl may be removed and the insulating layer 1840 filled inside the groove H1 may remain.

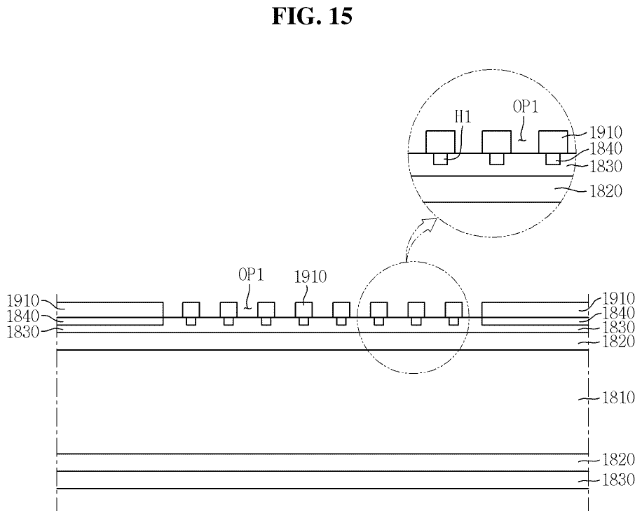

In an embodiment and referring to FIG. 15, a photoresist pattern 1910 including a plurality of first openings OP1 corresponding to the cell opening COP may be formed on the second inorganic layer 1830 including the insulating layer 1840. As illustrated in the drawing, the photoresist pattern 1910 may be disposed to overlap the groove H1 filled with the insulating layer 1840 and be formed to have a width greater than the width of the groove H1. Accordingly, the photoresist pattern 1910 may be formed to completely cover the groove H1 filled with the insulating layer 1840.

In an embodiment and referring to FIG. 16, the second inorganic layer 1830 located at the periphery of the plurality of grooves H1 may be etched using the photoresist pattern as a mask and may form the cell opening COP thereby exposing a mask membrane MM by etching the substrate 1810 and the first inorganic layer 1820 from the downward direction to which the rear surface of the substrate 1810 faces.

The process of etching the second inorganic layer 1830, according to an embodiment, may be as described below. The second inorganic layer 1830 located between the neighboring grooves H1 are etched using the photoresist pattern 1910 as a mask. Accordingly, the second inorganic layer 1830 overlapping the photoresist pattern 1910 and the insulating layer 1840 filled inside the groove H1 of the second inorganic layer 1830 is not etched and remains, and a cross-sectional structure of the mask membrane MM is completed. The cross-sectional structure of the mask membrane MM includes the second inorganic layer 1830 including the plurality of grooves H1 and the insulating layer 1840 filled inside the plurality of grooves H1.

The photoresist pattern 1910 may be removed after etching the second inorganic layer 1830.

According to an embodiment, a step of forming the cell opening COP may include a step of etching the first inorganic layer 1820 deposited on the rear surface of the substrate 1810, and a step of etching the substrate 1810, and etching the first inorganic layer 1820 deposited on the front surface of the substrate 1810. Here, the first inorganic layer 1820 deposited on the rear surface of the substrate 1810, the substrate 1810, and the first inorganic layer 1820 deposited on the front surface of the substrate 1810 may be sequentially etched. In addition, the etching of the first inorganic layer 1820 deposited on the rear surface of the substrate 1810, the substrate 1810, and the first inorganic layer 1820 deposited on the front surface of the substrate 1810 may proceed from the downward direction facing the rear surface of the substrate 1810.

According to an embodiment, the material of the second inorganic layer 1830 may be the same as the material of the insulating layer 1840 filled inside the groove H1.

According to an embodiment, the material of the second inorganic layer 1830 may be different from the material of the insulating layer 1840 filled inside the groove H1.

As described above, the method of manufacturing a mask, according to an embodiment, enables the cross-sectional structure of the mask membrane MM to include the second inorganic layer 1830 including the plurality of grooves H1 and the insulating layer 1840 filled inside the plurality of grooves H1. Accordingly, the risk of damage due to thin thickness of the mask membrane MM formed of inorganic layer may be reduced. In addition, the invention may reduce sagging of the mask membrane MM, and the bending defects of the mask membrane MM due to thin thickness of the mask membrane MM may be reduced.

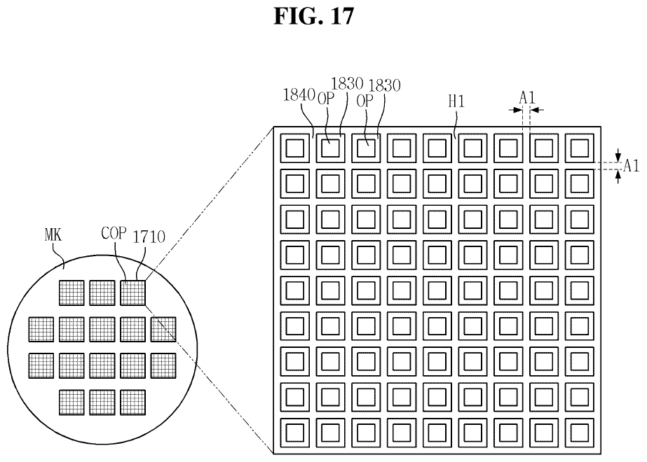

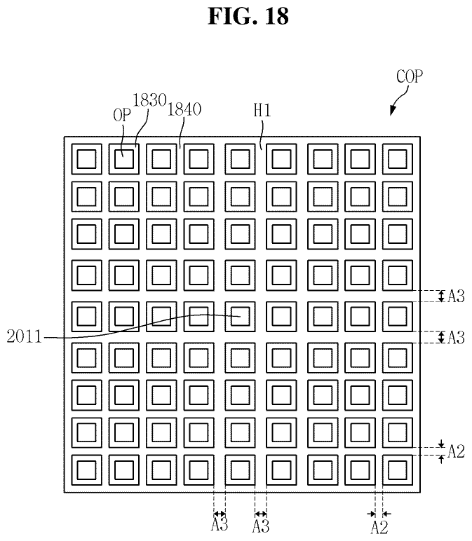

FIGS. 17 and 18 are plan views of a mask, according to an embodiment.

In an embodiment and referring to FIGS. 17 and 18, when the mask is viewed on a plane, a width of the second inorganic layer 1830 in which the insulating layer 1840 is filled (or a width of the insulating layer 1840) may be designed in various shapes.

According to an embodiment, as illustrated in FIG. 17, the width of each of the plurality of grooves H1 in which the insulating layer 1840 is filled may be uniform when the substrate 1810 is viewed on a plane. For example, the groove H1 filled with the insulating layer 1840 may be disposed to surround the periphery of the opening (i.e., the opening OP of the mask membrane MM) of the second inorganic layer 1830 forming the mask membrane when the mask is viewed on a plane, and a width A1 of the groove Hl may be overall uniform.

According to an embodiment, as illustrated in FIG. 18, when the substrate 1810 is viewed on a plane, the width of the plurality of grooves H1 filled with the insulating layer 1840 may not be uniform and may be designed to be different for each partial area. For example, when the mask is viewed on a plane, the groove H1 filled with the insulating layer 1840 may be disposed to surround the periphery of the opening (i.e., the opening OP of the mask membrane MM) of the second inorganic layer 1830 forming the mask membrane MM, and widths A2 and A3 of the groove H1 may not be uniform and may be designed to be different for each partial area. For example, when the substrate 1810 is viewed on a plane, the widths A2 and A3 of the plurality of grooves H1 filled with the insulating layer 1840 are formed to be different. The first groove H1 disposed adjacent to a center 2011 of the substrate 1810 has a first width A3, and when the substrate 1810 is viewed on a plane, the second groove H1 disposed further from the center 2011 of the substrate 1810 than the first groove Hl has the second width A2 which is smaller than the first width A3.

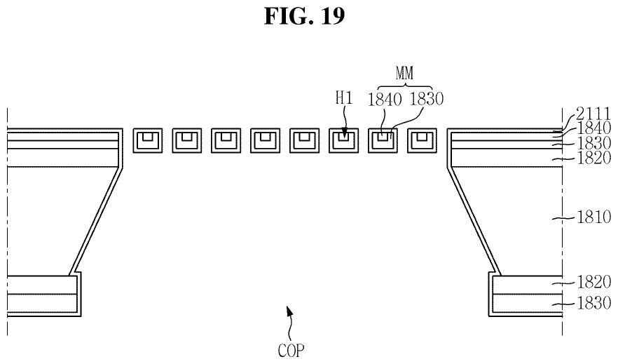

FIG. 19 is a cross-sectional view of a mask for illustrating processing steps of depositing a protection film on a mask, according to an embodiment.

In an embodiment and referring to FIG. 19, a method of manufacturing a mask may form an insulating layer 1840 (e.g., coating layer) on the entire surface of the mask in consideration of reusing the mask. For example, the method of manufacturing a mask further includes a step of forming a coating layer 2111 covering the entire surface of the first substrate 1810 and the entire surface of a mask membrane MM by using atomic layer deposition (ADL) method.

It will be able to be understood by one of ordinary skill in the art to which the invention belongs that the invention may be implemented in other specific forms without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to application should be construed as being included in the scope of the invention. Moreover, the embodiments or parts of the embodiments may be combined in whole or in part without departing from the scope of the invention.

What is claimed is:

1. A method of manufacturing a deposition mask, comprising:
depositing a first inorganic layer onto a substrate;
depositing a second inorganic layer onto the first inorganic layer;
forming a plurality of grooves in the second inorganic layer, and filling the plurality of grooves with an insulating layer;
forming a photoresist pattern including a plurality of first openings corresponding to a cell opening on the second inorganic layer;
etching the second inorganic layer located at a periphery of the plurality of grooves using the photoresist pattern as a mask; and
exposing the cell opening by etching the substrate and the first inorganic layer from a downward direction facing a rear surface of the substrate.

2. The method of claim 1, wherein exposing the cell opening includes exposing a mask membrane disposed in the cell opening.

3. The method of claim 2, wherein a cross-sectional structure of the mask membrane comprises the second inorganic layer including the plurality of grooves, and the insulating layer disposed inside the plurality of grooves.

4. The method of claim 3, wherein the material of the second inorganic layer is the same as the material of the insulating layer.

5. The method of claim 3, wherein the material of the second inorganic layer is different from the material of the insulating layer.

6. The method of claim 1, wherein the substrate contains silicon (Si).

7. The method of claim 1, wherein the first inorganic layer contains silicon oxide (SiOₓ).

8. The method of claim 1, wherein the second inorganic layer contains silicon nitride (SiNₓ).

9. The method of claim 1, wherein the insulating layer contains silicon oxide (SiOₓ) or silicon nitride (SiNₓ).

10. The method of claim 1, wherein, when the substrate is viewed on a plane, the width of the plurality of grooves is uniform.

11. The method of claim 1, wherein, when the substrate is viewed on a plane, the width of the plurality of grooves is not uniform and is differentially formed.

12. The method of claim 11, wherein, when the substrate is viewed on a plane,
a first groove disposed adjacent to the center of the substrate has a first width, and
a second groove, disposed to be further from the center of the substrate than the first groove, has a second width that is smaller than the first width.

13. The method of claim 3,
further comprising forming a coating layer which covers an entire surface of the substrate and an entire surface of the mask membrane using an atomic layer deposition (ALD) method.

14. A deposition mask comprising:
a substrate;
a first inorganic layer disposed on the substrate; and
a mask membrane disposed on the first inorganic layer,
wherein a cross-sectional structure of the mask membrane comprises a second inorganic layer including a plurality of grooves which are filled with an insulating layer.

15. The deposition mask of claim 14, wherein the material of the second inorganic layer is the same as the material of the insulating layer.

16. The deposition mask of claim 14, wherein the material of the second inorganic layer is different from the material of the insulating layer.

17. The deposition mask of claim 14, wherein the substrate contains silicon (Si).

18. The deposition mask of claim 14, wherein the first inorganic layer contains silicon oxide (SiOₓ), and
the second inorganic layer contains silicon nitride (SiNₓ).

19. The deposition mask of claim 14, wherein, when the substrate is viewed on a plane, the width of the plurality of grooves is filled with the insulating layer.

20. The deposition mask of claim 14, wherein, when the substrate is viewed on a plane,
a first groove disposed adjacent to the center of the substrate has a first width, and
a second groove, disposed further from the center of the substrate than the first groove, has a second width that is smaller than the first width.
